(19) United States
(12) Patent Application Publication
(10) Pub. No.: US 2023/0345610 A1
(43) Pub. Date: Oct. 26, 2023

(54) METHOD AND APPARATUS FOR MONITORING AN EXTREME ULTRAVIOLET RADIATION SOURCE

(71) Applicant: TAIWAN SEMICONDUCTOR MANUFACTURING COMPANY, LTD., Hsinchu (TW)

(72) Inventors: Yu-Kuang SUN, Hsinchu City (TW); Ming-Hsun TSAI, Hsinchu City (TW); Wei-Shin CHENG, Hsinchu City (TW); Cheng-Hao LAI, Taichung City (TW); Hsin-Feng CHEN, Yilan City (TW); Chiao-Hua CHENG, Tainan City (TW); Cheng Hsuan WU, New Taipei City (TW); Yu-Fa LO, Kaohsiung (TW); Jou-Hsuan LU, New Taipei City (TW); Shang-Chieh CHIEN, New Taipei City (TW); Li-Jui CHEN, Hsinchu City (TW); Heng-Hsin LIU, New Taipei City (TW)

(21) Appl. No.: 17/727,479

(22) Filed: Apr. 22, 2022

(51) Int. Cl. H05G 2/00; G03F 7/20

(52) U.S. Cl. CPC H05G 2/006; G03F 7/70033; G03F 7/70483

(57) ABSTRACT

In order to prevent long down-time that occurs with unexpected material depletion, an Inline Tin Stream Monitor (ITSM) system precisely measures the tin amount introduced by an in-line refill system and precisely estimates remaining runtime by measuring pressure level changes before and after in-line refill.

### BACKGROUND

One growing technique for semiconductor manufacturing is extreme ultraviolet (EUV) lithography. EUV employs scanners using light in the EUV spectrum of electromagnetic radiation, including wavelengths from about one nanometer (nm) to about one hundred nm. Many EUV scanners still utilize projection printing, similar to various earlier optical scanners, except EUV scanners accomplish it with reflective rather than refractive optics, that is, with mirrors instead of lenses.

EUV lithography employs a laser-produced plasma (LPP), which emits EUV light. The LPP is produced by focusing a high-power laser beam, from a carbon dioxide (CO₂) laser and the like, onto small fuel droplet targets of tin (Sn) in order to transition it into a highly-ionized plasma state. This LPP emits EUV light with a peak maximum emission of about 13.5 nm or smaller. The EUV light is then collected by a collector and reflected by optics towards a lithography exposure object, such as a semiconductor wafer. Malfunctions of the tin droplet generator adversely affect the semiconductor device production rates of an EUV device.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a diagram of a lithography apparatus in accordance with some embodiments.

FIG. 1B is a diagram of a source side and a scanner side in accordance with some embodiments.

FIG. 2A is a diagram of a supply monitoring apparatus in accordance with some embodiments.

FIG. 2B is a second diagram of a supply and monitoring apparatus in accordance with some embodiments.

FIG. 3A is a diagram of a droplet generation assembly in accordance with some embodiments.

FIG. 3B is a second diagram of a droplet generation assembly in accordance with some embodiments.

FIG. 4 is a flowchart of a supply monitoring process in accordance with some embodiments.

FIG. 5A and FIG. 5B are diagrams of a controller in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus/device may be otherwise oriented (rotated 90 degrees or at other orientations) and the spatially relative descriptors used herein may likewise be interpreted accordingly. In addition, the term “made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gratings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, the term “optic,” as used herein, is not meant to be limited to components which operate solely within one or more specific wavelength range(s) such as at the EUV output light wavelength, the irradiation laser wavelength, a wavelength suitable for metrology or any other specific wavelength.

In the present disclosure, the terms mask, photomask, and reticle are used interchangeably. In the present embodiment, the mask is a reflective mask. One embodiment of the mask includes a substrate with a suitable material, such as a low thermal expansion material or fused quartz. In various examples, the material includes TiO₂ doped SiO₂, or other suitable materials with low thermal expansion. The mask includes multiple reflective layers deposited on the substrate. The multiple layers include a plurality of film pairs, such as molybdenum-silicon (Mo/Si) film pairs (e.g., a layer of molybdenum above or below a layer of silicon in each film pair). Alternatively, the multiple layers may include molybdenum-beryllium (Mo/Be) film pairs, or other suitable materials that are configurable to highly reflect the EUV light. The mask may further include a capping layer, such as ruthenium (Ru), disposed on the ML for protection. The mask further includes an absorption layer, such as a tantalum boron nitride (TaBN) layer, deposited over the multiple layers. The absorption layer is patterned to define a layer of an integrated circuit (IC). Alternatively, another reflective layer may be deposited over the multiple layers and is patterned to define a layer of an integrated circuit, thereby forming an EUV phase shift mask.

In the present embodiments, the semiconductor substrate is a semiconductor wafer, such as a silicon wafer or other type of wafer to be patterned. The semiconductor substrate is coated with a resist layer sensitive to the EUV light in the present embodiment. Various components including those described above are integrated together and are operable to perform various lithography exposing processes. The lithography system may further include other modules or be integrated with (or be coupled with) other modules.

A lithography system is essentially a light projection system. Light is projected through a ‘mask’ or ‘reticle’ that constitutes a blueprint of the pattern that will be printed on a workpiece. The blueprint is four times larger than the intended pattern on the wafer or chip. With the pattern encoded in the light, the system's optics shrink and focus the pattern onto a photosensitive silicon wafer. After the pattern is printed, the system moves the wafer slightly and makes another copy on the wafer. This process is repeated until the wafer is covered in patterns, completing one layer of the eventual semiconductor device. To make an entire microchip, this process will be repeated one hundred times or more, laying patterns on top of patterns. The size of the features to be printed varies depending on the layer, which means that different types of lithography systems are used for different layers, from the latest-generation EUV systems for the smallest features to older deep ultraviolet (DUV) systems for the largest.

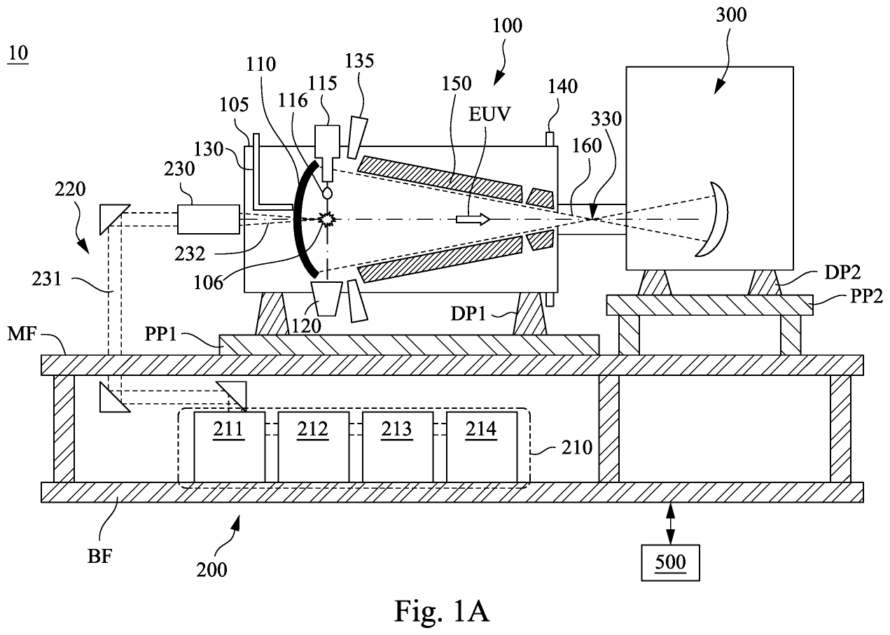

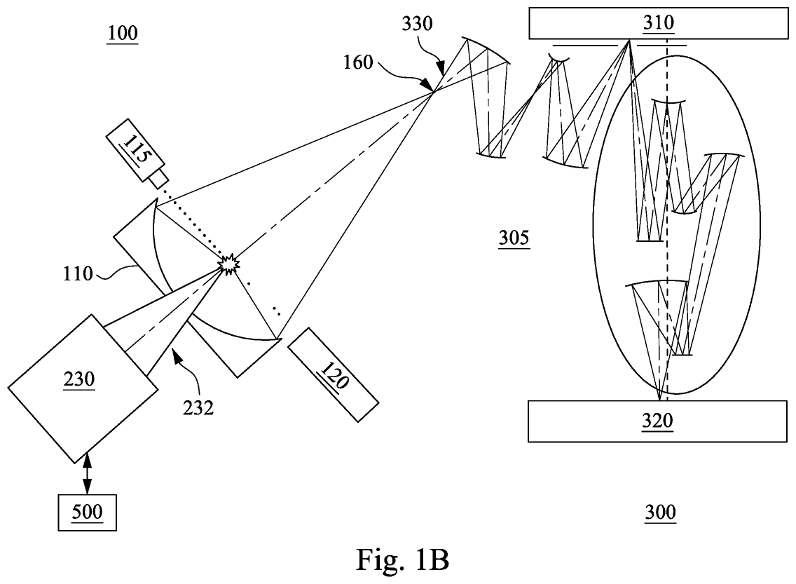

FIG. 1A is a schematic and diagrammatic view of an EUV lithography (EUVL) system 10. The EUVL system 10 includes an EUV radiation source apparatus 100 (sometimes referred to herein as a “source side” in reference to it or one or more of its relevant parts) to generate EUV light, an exposure tool 300 (sometimes referred to herein as a “scanner” or “scanner side” in reference to it or one or more of its relevant parts), and an excitation laser source apparatus 200. As shown in FIG. 1A, in some embodiments, the EUV radiation source apparatus 100 and the exposure tool 300 are installed on a main floor (MF) of a clean room, while the excitation laser source apparatus 200 is installed in a base floor (BF) located under the main floor. In some embodiments, each of the EUV radiation source apparatus 100 and the exposure tool 300 are placed over pedestal plates PP1 and PP2 via dampers DP1 and DP2, respectively. In various embodiments, the EUV radiation source apparatus 100 and the exposure tool 300 are coupled to each other at a junction 330 by a coupling mechanism, which may include a focusing unit (not shown).

In various embodiments, the EUVL system 10 is designed to expose a resist layer to EUV light (or EUV radiation), where the resist layer is a material sensitive to the EUV light. The EUVL system 10 employs the EUV radiation source apparatus 100 to generate EUV light having a wavelength ranging between about 1 nanometer (nm) and about 100 nm, in various embodiment. In one particular example, the EUV radiation source apparatus 100 generates EUV light with a wavelength centered at about 13.5 nm. In various embodiments, the EUV radiation source apparatus 100 utilizes LPP to generate the EUV radiation.

As further shown in FIG. 1A, the EUV radiation source apparatus 100 includes a target droplet generator 115 and an LPP collector 110, both enclosed by a chamber 105 in various embodiments. In such embodiments, the target droplet generator 115 generates a plurality of target droplets 116. In some embodiments, the target droplets 116 are tin (Sn) droplets. In some embodiments, the target droplets 116 have a diameter of about 30 microns (μm). In some embodiments, the target droplets 116 are generated at a rate about fifty droplets per second and are introduced into an excitation zone 106 at a speed of about seventy meters per second (m/s or mps). Other droplet material can also be used for forming the target droplets 116, for example, a liquid material such as a eutectic alloy containing Sn and lithium (Li).

As the target droplets 116 move through the excitation zone 106, pre-pulses (not shown) of the laser light first heat the target droplets 116 and transform them into lower-density target plumes, in various embodiments. Then, in various embodiments, the main pulse 232 of laser light is directed through windows or lenses (not shown) into the excitation zone 106 to transform the target plumes into a LPP. In some embodiments, the windows or lenses are composed of a suitable material substantially transparent to the pre-pulses and the main pulse 232 of the laser. In such embodiments, the generation of the pre-pulses and the main pulse 232 is synchronized with the generation of the target droplets 116. In various embodiments, the pre-heat laser pulses have a spot size about 100 μm or less, and the main laser pulses have a spot size about 200-300 μm. A delay between the pre-pulse and the main pulse 232 is controlled to allow the target plume to form and to expand to an optimal size and geometry, in various embodiments. In such embodiments, when the main pulse 232 heats the target plume, a high-temperature LPP is generated. The LPP emits EUV radiation, which is collected by one or more mirrors of the LPP collector 110, in such embodiments. More particularly, in various embodiments, the LPP collector 110 has a reflection surface that reflects and focuses the EUV radiation for the lithography exposing processes. In some embodiments, a droplet catcher 120 is installed opposite the target droplet generator 115. The droplet catcher 120 is used for catching excess target droplets 116 for example, when one or more target droplets 116 are purposely or otherwise missed by the pre-pulses or main pulse 232.

In various embodiments, the target droplet generator 115 generates tin droplets along a vertical axis. In such embodiments, each droplet is hit by a CO₂ laser pre-pulse (PP) and will responsively change its shape into a “pancake” during travel along the axial direction. After a time duration (MP to PP delay time), the pancake is hit by a CO₂ laser main (MP) proximate to a primary focus (PF) in order to generate an EUV light pulse, in various embodiments. In such embodiments, the EUV light pulse is then collected by an LPP collector 100 and delivered to the scanner side for use in wafer exposure.

In various embodiments, the LPP collector 110 includes a proper coating material and shape to function as a mirror for EUV collection, reflection, and focusing. In some embodiments, the LPP collector 110 is designed to have an ellipsoidal geometry. In some embodiments, the coating material of the collector 100 is similar to the reflective multilayer of an EUV mask. In some examples, the coating material of the LPP collector 110 includes multiple layers, such as a plurality of molybdenum/silicon (Mo/Si) film pairs, and may further include a capping layer (such as ruthenium (Ru)) coated on the multiple layers to substantially reflect the EUV light.

In various embodiments, the main pulse 232 is generated by the excitation laser source apparatus 200. In some embodiments, the excitation laser source apparatus 200 includes a pre-heat laser and a main laser. In such embodiments, the pre-heat laser generates the pre-pulse that is used to heat or pre-heat the target droplet 116 in order to create a low-density target plume, which is subsequently heated (or reheated) by the main pulse 232, thereby generating increased emission of EUV light.

In various embodiments, the excitation laser source apparatus 200 includes a laser generator 210, laser guide optics 220 and a focusing apparatus 230. In some embodiments, the laser generator 210 includes a carbon dioxide (CO₂) laser source or a neodymium-doped yttrium aluminum garnet (Nd:YAG) laser source. In various embodiments, the laser light 231 generated by the laser generator 210 is guided by the laser guide optics 220 and focused into the main pulse 232 of the excitation laser by the focusing apparatus 230, and then introduced into the EUV radiation source apparatus 100 through one or more apertures, such as the aforementioned windows or lenses.

In such an EUV radiation source apparatus 100, the LPP generated by the main pulse 232 creates physical debris, such as ions, gases, and atoms of the droplet 116, along with the desired EUV light. In operation of the EUVL system 10, there is an accumulation of such debris on the LPP collector 110, and such physical debris exits the chamber 105 and enters the exposure tool 300 (i.e., the “scanner side”) as well as the excitation laser source apparatus 200.

In various embodiments, a buffer gas is supplied from a first buffer gas supply 130 through the aperture in the LPP collector 110 by which the main pulse 232 of laser light is delivered to the tin droplets 116. In some embodiments, the buffer gas is hydrogen (H₂), helium (He), argon (Ar), nitrogen (N₂), or another inert gas. In certain embodiments, H₂ is used, since H radicals generated by ionization of the buffer gas can also be used for cleaning purposes. Furthermore, H₂ absorbs the least amount of EUV light produced by the source side, and thus absorbs the least light used by the semiconductor manufacturing operations performed in the scanner side of the lithography apparatus 10. The buffer gas can also be provided through one or more second buffer gas supplies 135 toward the LPP collector 110 and/or around the edges of the LPP collector 110. Further, and as described in more detail later below, the chamber 105 includes one or more gas outlets 140 so that the buffer gas is exhausted outside the chamber 105.

Hydrogen gas has low absorption of the EUV radiation. In various embodiments, hydrogen gas reaching to the coating surface of the LPP collector 110 reacts chemically with a metal of the target droplet 116, thus forming a hydride, e.g., metal hydride. In embodiments where Sn is used as the target droplet 116, stannane (SnH₄), which is a gaseous byproduct of the EUV generation process, is formed. In such embodiments, the gaseous SnH₄ is then pumped out through the outlet 140. However, it is difficult to exhaust all gaseous SnH₄ from the chamber and to prevent the Sn debris and SnH₄ from entering the exposure tool 300 and the excitation laser source apparatus 200. To trap the Sn, SnH₄ or other debris, one or more debris collection mechanisms or devices 150 are employed in the chamber 105, in some embodiments. In various embodiments, a controller 500 controls the EUV lithography system 10 and/or one or more of its components shown in and described above with respect to FIG. 1A.

As shown in FIG. 1B, in various embodiments, the exposure tool 300 (e.g., the “scanner”) includes various reflective optic components, such as convex/concave/flat mirrors, a mask holding mechanism 310 including a mask stage (i.e., a reticle stage), and wafer holding mechanism 320. In various embodiments, the EUV radiation generated by the EUV radiation source apparatus 100 and focused at intermediate focus 160 is guided by the reflective optical components 305 onto a mask (not shown) secured on the reticle stage 310, also referenced as a “mask stage” herein. In some embodiments, the distance from the intermediate focus 160 and the reticle disposed in the scanner side is approximately 2 meters. In some embodiments, the reticle size is approximately 152 mm by 152 mm. In some embodiments, the reticle stage 310 includes an electrostatic chuck, or ‘e-chuck,’ (not shown) to secure the mask. The EUV light patterned by the mask is used to process a wafer supported on wafer stage 320. Because gas molecules absorb EUV light, the chambers and areas of the EUVL system 10 used for EUV lithography patterning are maintained in a vacuum or a low-pressure environment to avoid EUV intensity loss. In various embodiments, the controller 500 controls one or more of the components of the EUVL system 10 as shown in and described with respect to FIG. 1B above, as well as various other components introduced below.

As will be described in further detail below, full depletion of droplet material during operation of the droplet generator will cause extended downtime of the EUVL system 10. The high temperature and pressure environment required to supply droplet material from a reservoir to the droplet generator 115 makes direct measurement of droplet material levels by sensors or the like impossible during operation of a modelized vessel tool, such as the EUVL system 10. Rather than using a low accuracy method for indirect droplet material estimation during operation, such as using estimation formulae and algorithms employing complicated operating parameters, or manually changing system runtime to prevent droplet material depletion, in various embodiments herein, an Inline Refill System, such as a supply and monitoring system having an Inline Tin Stream Monitor (ITSM) system, is introduced. In such embodiments, the ITSM system monitors tin droplet material levels being provided to the droplet generator 115 by pressure measurement near an inlet of the droplet generator 115, and provides a pre-alarm function configured to prevent the droplet generator 115 from running too low on droplet material (such as tin), thereby avoiding an unscheduled long downtime of the EUVL system 10. In various embodiments as described in more detail below, the ITSM system includes a pressure sensor in communication with an alarm system for such purposes.

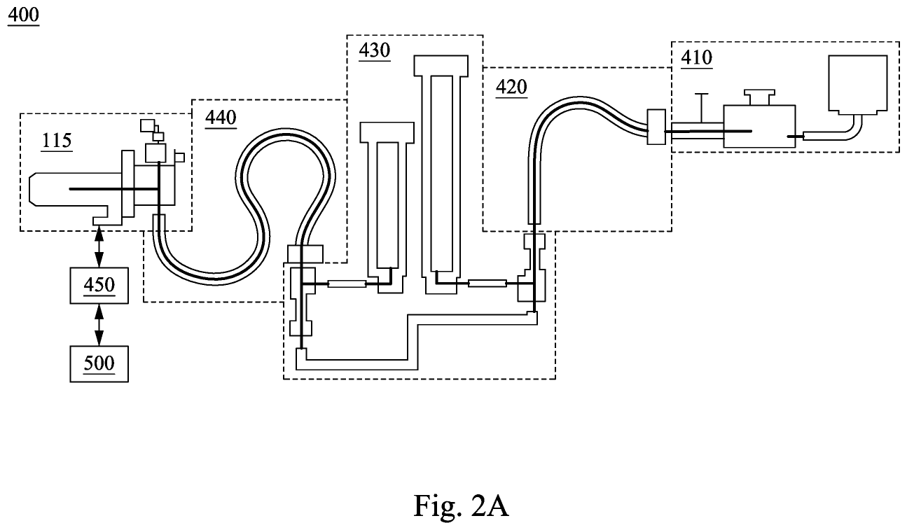

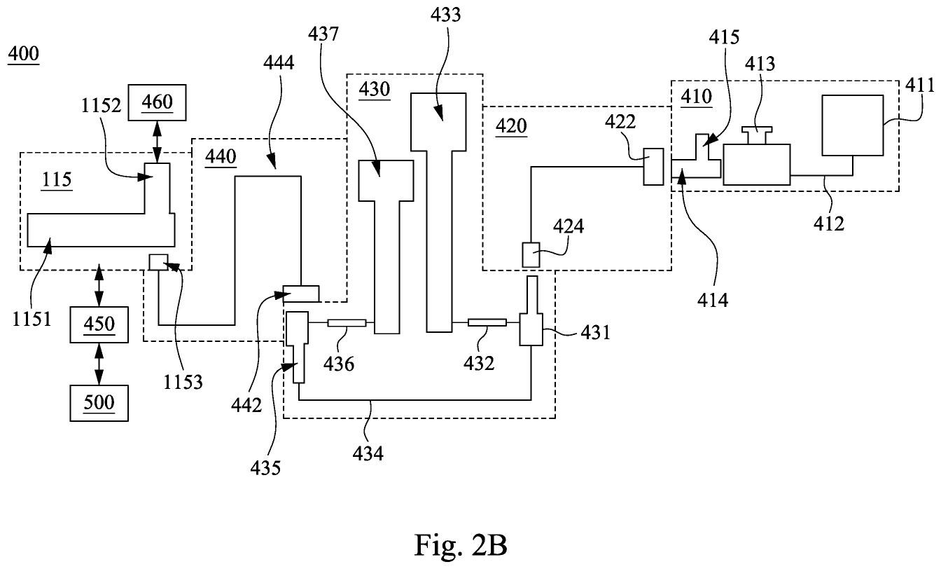

Turning to FIG. 2A, there is shown a diagram of the supply and monitoring apparatus 400, which operates in conjunction with the droplet generator 115 in accordance with various embodiments. In various embodiments of the supply and monitoring system 400, there are five modules having various components. In such embodiments, the supply and monitoring apparatus 400 includes a Refill and Priming Assembly (RPA) 410, a Tin Refill Assembly (TRA) 420, a Tin Storage Assembly (TSA) 430, a Tin Transfer Assembly (TTA) 440, an Inline Tin Stream Monitor (ITSM) 450, and a controller 500, the functions, components and inter-operability of which will be described in turn in more detail below.

FIG. 2B is a more detailed diagram of the droplet generator 115 and the supply and monitoring apparatus 400 in accordance with various embodiments. As shown therein, in various embodiments, the components of a droplet generator 115 include a nozzle 1151, a Service Freeze Valve (SFV) 1152 and an inlet port 1153. In various embodiments, the outer body of the nozzle 1151 is made of a metal, such as titanium or stainless steel. In some embodiments, the tip of the nozzle 1151 where the droplets are generated, is made of a material that can withstand the high temperatures required to maintain the target droplet material in a molten state, and not react chemically therewith. Accordingly, in some embodiments, the tip of the nozzle 1151 is comprised of a strong, non-fragile material, for example a metal (e.g., titanium), a ceramic, silicon or a silicon-based compound, such as silicon nitride. In some embodiments, the tip is made of silicon coated with silicon nitride. Such a tip is able to withstand high pressures within the nozzle, and therefore, high gas pressures can be used to force the molten droplet material through the nozzle 1151.

In some embodiments, the SFV 1152 is located at or in proximity to an end of the nozzle 1151 opposite the tip. In various embodiments, the SFV 1152 is open during operation of the droplet generator 115. When maintenance or servicing of the radiation source 100 is required, the SFV 1152 closes to seal the nozzle 1151. The chamber 105 of the EUV radiation source 100 is maintained under vacuum or low pressure during operation of the EUVL system 10.

Because EUV light is absorbed by most materials, including gases, it is necessary to operate the EUVL system 10 under low pressure or vacuum to prevent loss of exposure light energy during imaging operations in various embodiments. Accordingly, in some embodiments, the vacuum chamber 105 is opened when it is necessary to perform maintenance or service the EUVL system 10. Exposing the vacuum chamber 105 to the ambient atmosphere introduces oxygen, which readily reacts with heated metals to form metal oxides. For example, the oxygen may react with molten tin in the nozzle 1151 to form tin oxides, such as stannous oxide (SnO) and stannic oxide (SnO₂). In some embodiments, the molten tin is maintained at a temperature of about 250 degrees Celsius (° C.). At this temperature tin oxides are solid. Thus, any tin oxides that form will precipitate out of the molten tin. The tin oxides form solid particles that clog the nozzle tip 1151 or coat the collector mirror, thereby reducing mirror reflectivity. The tin oxide particles also deposit on optics in the scanner side 300 and thereafter interfere with the pattern imaging. To prevent the formation of tin oxide particulate contamination, the isolation valve 1152 closes to seal the nozzle 115 and prevent oxygen from entering the nozzle 1150 and reacting with molten droplet material in some embodiments.

In various embodiments, a gas and vacuum delivery system 460 is provided in communication with the droplet generator 115. To prevent the aforementioned formation of tin oxide particulate contamination, the gas and vacuum delivery system 460 closes to seal the nozzle 1151 and prevent oxygen from entering the nozzle 1151 and reacting with molten droplet material in some embodiments.

In some embodiments, an inert gas is provided to the nozzle 1151 to provide an inert gas to the nozzle 1151 to further prevent oxygen or other reactive gases from reacting with the molten target material. When the EUVL system 10 is shut down for servicing or maintenance, inert gas is introduced to nozzle 1151 in some embodiments. In some embodiments, an inert gas line (not shown) is connected to a source of the inert gas (not shown) for supplying the inert gas to the gas and vacuum delivery system 460. In some embodiments, the inert gas is helium, neon, argon, xenon, or nitrogen.

In various embodiments, the inlet port 1153 receives droplet material from the supply and monitoring apparatus 400. In some embodiments, the droplet material is tin. Such embodiments will be referenced herein, although other embodiments are readily contemplated. In some embodiments, the tin is provided to the droplet generator 115 under high pressure and at a high temperature so that the tin is in a molten state.

In various embodiments, one module of the supply and monitoring apparatus 400 is the Refill and Priming Assembly (RPA) 410 that functions to purify and refill tin that is ultimately supplied to the droplet generator 115. In some embodiments, the RPA 410 includes the following components: a Tin Priming Tank (TPT) 411, a Gate Valve Freeze Line (GVFL) 412, a Tin Refill Tank (TRT) 413, a Refill Service Port (RSP) 414, and a Refill Service Freeze Valve (RSFV) 415, the functions of which will now be described in turn. In some embodiments, the TPT 411 receives tin from an external supply source, and then applies a high temperature (such as 250 degrees C.) and a vacuum to purify the droplet material (i.e., priming). In some embodiments, the GVFL 412 isolates the TPT during priming (or during shutdown of the EUVL system 10) and opens to allow the purified droplet material to flow from the TPT 411 to the TRT 413 after purification. In some embodiments, the TRT 413 pressurizes the purified droplet material for supply to the reservoir components described later below. In some embodiments, the RSFV 415 isolates the TRT 413 during filling thereof and opens to allow the pressurized and purified droplet material to flow to downstream modules of the supply and monitoring apparatus 400 through the RSP 414 during operation of the EUVL system 10. In various embodiments, the droplet material is pressurized to 14 to 16 pounds per square inch (PSI), such as 15 PSI, by various components of the RPA 410 during operation.

In various embodiments, the TRA 420 comprises a connection line 422 that runs from the RSP 414 to a refill freeze valve (RFV) 424. During refill of the RPA 410 or during shutdown of the EUVL system 10, the RFV 424 closes in some embodiments in order to prevent damage to other system modules and components. During refill of the Tin Storage Assembly (TSA) 430, which ultimately supplies the droplet generator 115 in some embodiments, the RFV 424 opens to allow flow of the purified and pressurized droplet material to flow from the RPA 410 to the TSA 430.

In various embodiments, the TSA 430 includes the following components: a Refill Freeze Valve Manifold (RFVM) 431, a Refill Reservoir Flex Line (RRFL) 432, a Refill Reservoir (RR) 433 (also referred to herein as a secondary reservoir or a reserve reservoir), an Internal Flex Line (IFL) 434, a Primary Freeze Valve (PFV) 435, a Primary Reservoir Flex Line (PRFL) 436, and a Primary Reservoir (PR) 437, the functions of each of which will now be described in turn. In various embodiments, the TSA 430 includes both the RR 433 and the PR 437. In some embodiments, the RR 433 and the PR 437 are interconnected. In some embodiments, the RR 433 and the PR 437 are connected in parallel to provide droplet material to the droplet generator 115. In some embodiments, the RR 433 and the PR 437 are connected in series to provide droplet material to the droplet generator 115. In some embodiments, the provision of the RR 433 allows for more rapid refill of the droplet material, such as molten tin, than systems having a single reservoir. In such embodiments, the RFVM 431 receives the flow of droplet material from the RFV 424 and provides the droplet material to the RR 433 via the RRFL 432. In some embodiments, the RR 433 works alone with the RPA 410 and the TRA 420 for droplet material refill to the TSA 430. In such embodiments, the RR 433 does not transfer droplet material to the PR 437 during refill operations.

In some embodiments, after refill of the RR 433 is complete (or during shutdown of the EUVL system 10), the RFVM 431 will close to prevent further droplet material from being delivered to the RR 433 by the TRA 420. In such embodiments, the RFVM 431 will then allow flow of droplet material from the RR 433 to the PR 437 via the IFL 434 to the PFV 436 and then through the PRFL 436, until the droplet material levels in the RR 433 and the PR 437 are substantially equal and stabilized, after which the operation of the EUVL system 10 is recommenced. In some such embodiments, the RR 433 has a greater volume or storage capacity than the PR 437, such that when the RR 433 is filled, sufficient droplet material is available to fully fill the storage capacity of the PR 437 upon transfer of droplet material thereto. In various embodiments, the RR 433 and the PR 437 are substantially cylindrical or rectangular. In various embodiments, the RR 433 and the PR 437 are disposed vertically with the TSA 430. In some embodiments, a bottom of the RR 433 is disposed at substantially the same height (i.e., within 1-10 cm) as a bottom of the PR 437 in order to allow gravity and the fluid properties of the droplet material to stabilize the levels of droplet material in the RR 433 and the PR 437 during refill operations, as described herein.

In various embodiments, after refill operations are complete and the droplet material levels are stabilized in the RR 433 and the PR 437, operation of the droplet generator 115 and the EUVL system 10 are allowed to start and/or recommence. In various embodiments, during operations of the EUVL system 10, the RR 433 continuously interoperates with the PR 437 to supply droplet material to the droplet generator 115 by providing the droplet material through the PFV 435 to the TTA 440 in the manners described herein and other manners readily apparent to one of ordinary skill in the art. In some embodiments, the RR 433 and the PR 437 heat the droplet material to temperatures between 200 degrees C. and 30 degrees C., such as 260 degrees C. In various embodiments, heating is accomplished through the use of thermocouples or other suitable heating elements. In some embodiments, the RR 433 and the PR 437 pressurize the droplet material to pressures between 3500 psi and 4500 psi, such as 4000 psi, using any suitable pressurization apparatus.

In various embodiments, the TTA 440 includes a primary valve freeze manifold (PVFM) 442 for receiving droplet material from the PFV 435, and a flex line 444 (sometimes referred to herein a supply line) for transferring the droplet material to the inlet port 1153 of the droplet generator 115. In various embodiments, the pressure in the supply line is between 14 and 16 psi, such as 15 psi, during normal operation of the EUVL system 10 when the RR 433 and the PR 437 are sufficiently full of droplet material. However, this pressure has been observed to rise tremendously, such as to 4000 psi, when droplet material in the RR 433 and the PR 437 is depleted or approaches substantial depletion.

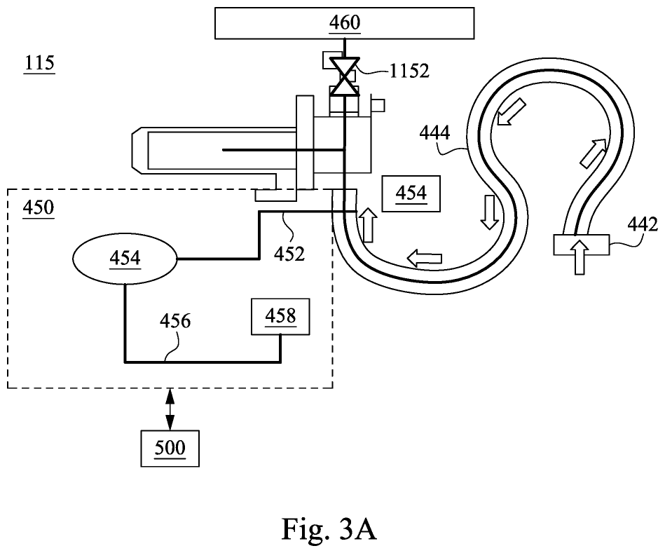

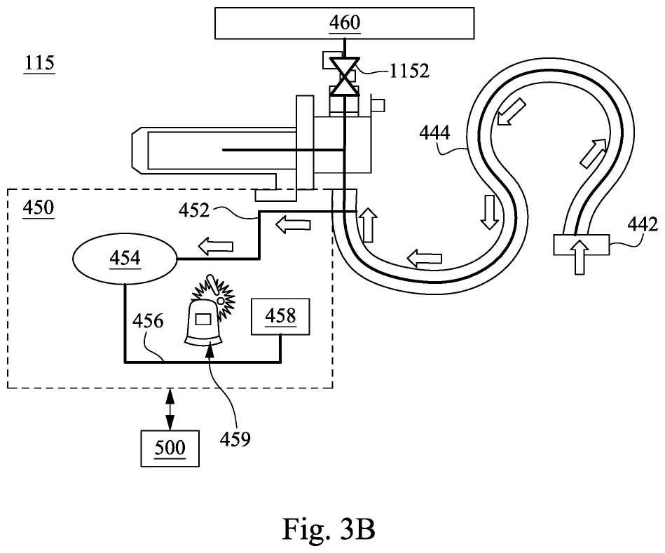

FIG. 3A is a diagram of a droplet generator 115 in conjunction with an ITSM 450, in accordance with some embodiments. In various embodiments, the ITSM 450 is provided in communication with the TTA 440 for monitoring the pressure within the supply line, such as a flex line 444. In some embodiments, the ITSM 450 includes a pressure sensor 454 for monitoring the pressure. In various embodiments, the pressure sensor 454 is any useful pressure sensor. In some embodiments, the pressure sensor 454 is intrusively disposed within the flex line 444 within the stream of the droplet material for monitoring the pressure therein. In other embodiments, the pressure sensor 454 is non-intrusively disposed on a sidewall within the flex line 444 for monitoring the pressure therein so as not to interfere with the flow of droplet material.

In some embodiments, the ITSM system 450 includes the pressure sensor 454 connected to the flex line 444 proximate to the inlet 1153 (and external to the droplet generator 115 in various embodiments) by a conduit 452. In some such embodiments, the conduit 452 is disposed within 1 to 10 cm of the inlet external to the droplet generator 115. In such embodiments, the proximity allows for a determination that the droplet material being supplied to the droplet generator 115 is depleted, whereas at other locations, a pressure increase may instead indicate a malfunction of another component of the supply and monitoring apparatus 400. In some embodiments, the conduit instead extends through a sidewall of the flex line 444 and the pressure sensor 454 is disposed at a useful distance from the conjunction of the conduit 452 and the flex line 444 such that the pressure sensor 454 may monitor the pressure within the flex line 444 without being substantially sullied or contaminated by the droplet material flowing through the flex line 444. In various embodiments, an alarm system 458 is connected to the pressure sensor by communication line 456. In various embodiments, the alarm system 458 is in communication with the controller 500 to indicate an alarm (i.e., alarm 459 of FIG. 3B) when high pressure or a sufficient pressure spike is detected by the pressure sensor 454.

In alternate embodiments, the pressure sensor 454 and/or the conduit 452 are disposed further upstream from the inlet 1153 on the flex line 444, or in other areas of the supply and monitoring apparatus 400, in order to measure the status of other components thereof.

When the EUVL system 10 is in normal operation, TTA 440 should be filled with liquid tin, which is applied at 4000 psi pressure by the droplet generator 115 to dispense molten tin droplets. During normal operation of the EUVL system 10, the ITSM 450 will be in an idle state with a low pressure value of 14-16 psi, such as 15 psi, because the flex line 444 is fully filled by the molten tin. As well during normal operation, in some embodiments, the tin level in the TSA 430 and TTA 440 will gradually decrease as the droplet generator 115 consumes the tin material. When the tin stream level becomes too low, the pressure sensor 454 in the ITSM 450 will detect a high pressure forming gas and will eventually spike to reach a high pressure status, such as approximately 4000 psi as supplied by the PR 437 and the RR 433, in some embodiments. In some embodiments, the change in pressure will be a sharp and immediate increase (i.e., a spike) that happens over a short period of time (such as 1 to 30 seconds). Subsequently, the alarm system 458 will trigger an alarm 459 as shown in FIG. 3B. The alarm system 458 will be triggered to warn operators or the controller 500 that the tin level in the TSA 430 is low. Before the droplet generator 115 runs out of tin, there will be about 5-10 hours to refill tin to the modules of the supply and monitoring system 400.

In some embodiments, when changes in the pressure are detected by the pressure sensors 454, the controller 500 performs a determination based on a value of pressure and/or a changing rate of the pressure measured by the pressure sensors 454. In some embodiments, the pressure sensor 454 includes a logic circuit programmed to generate a predetermined signal when the detected variation in pressure measurement is not within an acceptable range. For example, a signal is generated when the detected variation in a pressure measurement is above a certain threshold value (i.e., greater than about 20 psi) in some embodiments. In some embodiments, an expected minimum variation in pressure measurement is determined based on an average variation in pressure measurement for a largest change. In some embodiments, the expected minimum variation in pressure measurement is, for example, one standard deviation or two standard deviations more than the average variation in flow rate measurement determined for the largest change. In such embodiments, the alarm 459 is triggered when a number of standard deviations are surpassed in an established period of time, which is recognized by the controller 500 as a pressure spike. In various embodiments, upon determining that the TSA 430 requires refill of the droplet material, the controller 500 may perform one or more of the following operations: trigger the TRT 413 to refill the RR 433, shutdown the tin droplet generator 115 and shutdown the EUVL system 10. In alternate embodiments, a gas monitor (not shown) may be used in place of a pressure sensor and when an amount of monitored gas in the droplet stream supplied to the droplet generator 115 increases above a threshold value.

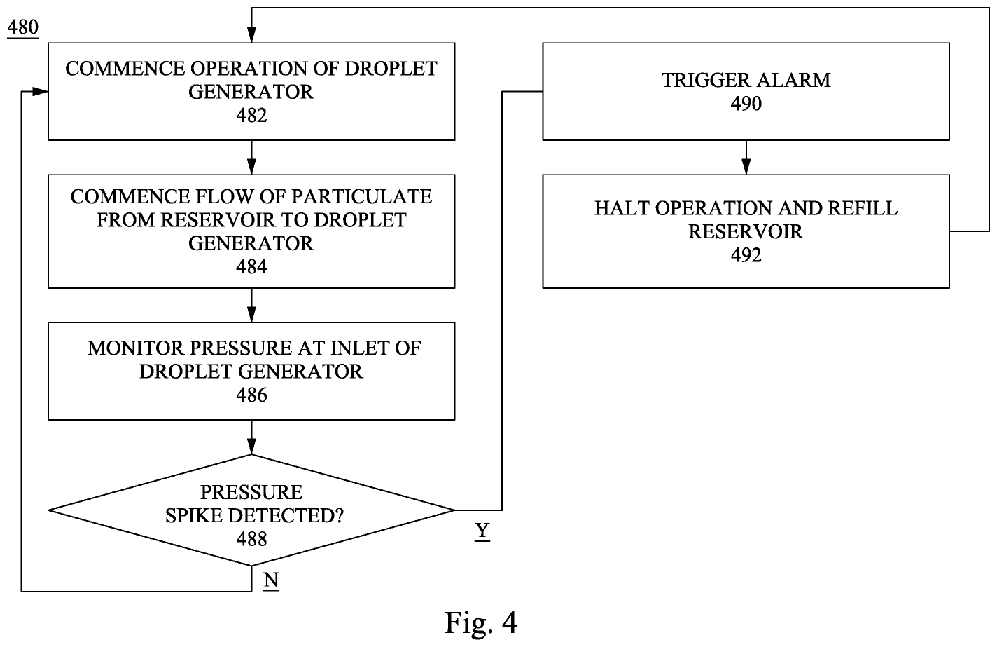

FIG. 4 is a flowchart of an exemplary supply monitoring process 400 performed by the various components of the supply and monitoring system 400 in conjunction with the controller 500 in accordance with some embodiments. First, at operation 482, operation of the droplet generator 115 commences. During normal operation, droplet material flows from the PR 437 and the RR 433 to the droplet generator 115 at a steady pressure (operation 484). During normal operation the pressure sensor 454 of the ITSM 450 monitors the pressure of the droplet material near the inlet 1153 of the droplet generator 115 (operation 486). If a pressure spike or other significant pressure change is detected (operation 486), an alarm 459 is triggered (operation 490). In such circumstance in various embodiments, operation of the droplet generator 115 and the EUVL system 10 are halted and the RR 433 of the TSA 430 is refilled via the RPA 415, after which operation of the EUVL system 10 may resume.

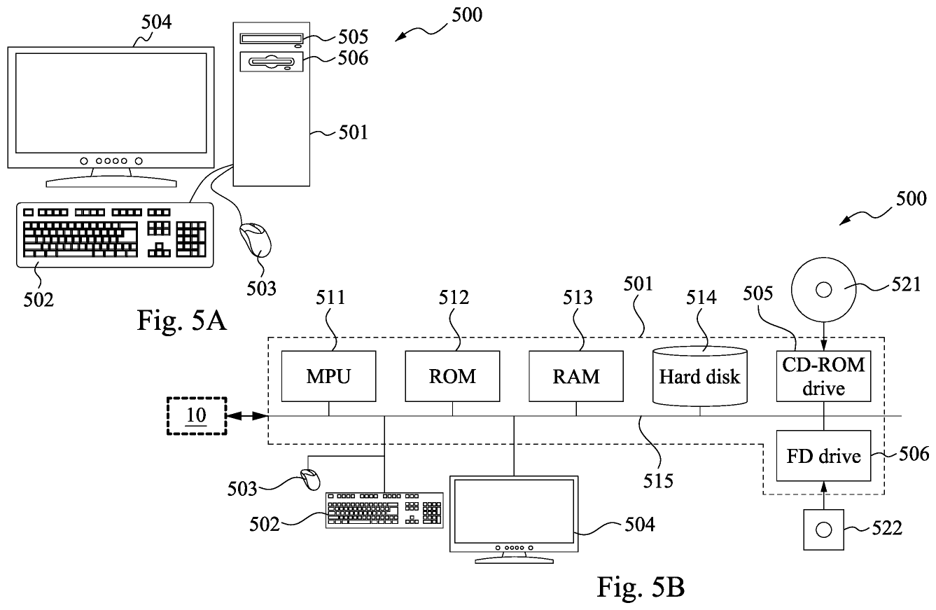

FIG. 5A and FIG. 5B illustrate a computer system 500 for controlling the system 10 and its components in accordance with various embodiments of the present disclosure. FIG. 5A is a schematic view of a computer system 500 that controls the EUVL system 10 of FIGS. 1A-1B. In some embodiments, the computer system 500 is programmed to initiate a process for monitoring tin level and provide an alert that refill is required. In some embodiments, manufacturing of semiconductor devices by the EUVL system 10 is halted in response to such an alarm until refill is achieved. As shown in FIG. 5A, the computer system 500 is provided with a computer 501 including an optical disk read only memory (e.g., CD-ROM or DVD-ROM) drive 505 and a magnetic disk drive 506, a keyboard 502, a mouse 503 (or other similar input device), and a monitor 504.

FIG. 5B is a diagram showing an internal configuration of the computer system 500. In FIG. 5B, the computer 501 is provided with, in addition to the optical disk drive 505 and the magnetic disk drive 506, one or more processors 511, such as a micro-processor unit (MPU) or a central processing unit (CPU); a read-only memory (ROM) 512 in which a program such as a boot up program is stored; a random access memory (RAM) 513 that is connected to the processors 511 and in which a command of an application program is temporarily stored, and a temporary electronic storage area is provided; a hard disk 514 in which an application program, an operating system program, and data are stored; and a data communication bus 515 that connects the processors 511, the ROM 512, and the like. Note that the computer 501 may include a network card (not shown) for providing a connection to a computer network such as a local area network (LAN), wide area network (WAN) or any other useful computer network for communicating data used by the computer system 500 and the EUVL system 10. In various embodiments, the controller 500 communicates via wireless or hardwired connection to the EUVL system 10 and its components.

The program for causing the computer system 500 to execute the process for controlling the EUVL system 10 of FIGS. 1A-1B, and components thereof and/or to execute the process for the method of manufacturing a semiconductor device according to the embodiments disclosed herein are stored in an optical disk 521 or a magnetic disk 522, which is inserted into the optical disk drive 505 or the magnetic disk drive 506, and transmitted to the hard disk 514. Alternatively, the program is transmitted via a network (not shown) to the computer system 500 and stored in the hard disk 514. At the time of execution, the program is loaded into the RAM 513. The program is loaded from the optical disk 521 or the magnetic disk 522, or directly from a network in various embodiments.

The stored programs do not necessarily have to include, for example, an operating system (OS) or a third party program to cause the computer 501 to execute the methods disclosed herein. The program may only include a command portion to call an appropriate function (module) in a controlled mode and obtain desired results in some embodiments. In various embodiments described herein, the controller 500 is in communication with the lithography system 10 to control various functions thereof.

The controller 500 is coupled to the EUVL system 10 in various embodiments. The controller 500 is configured to provide control data to those system components and receive process and/or status data from those system components. For example, the controller 500 comprises a microprocessor, a memory (e.g., volatile or non-volatile memory), and a digital I/O port capable of generating control voltages sufficient to communicate and activate inputs to the processing system 100, as well as monitor outputs from the EUVL system 10. In addition, a program stored in the memory is utilized to control the aforementioned components of the EUVL system 10 according to a process recipe. Furthermore, the controller 500 is configured to analyze the process and/or status data, to compare the process and/or status data with target process and/or status data, and to use the comparison to change a process and/or control a system component. In addition, the controller 500 is configured to analyze the process and/or status data, to compare the process and/or status data with historical process and/or status data, and to use the comparison to predict, prevent, and/or declare a fault or alarm.

In accordance with the foregoing, an improved EUVL system 10 prevents the droplet generator 115 from running out of tin, where depletion of such supply would cause an operational delay of between six hours and one day. Such precise monitoring of tin supply levels thus improve parts lifetime by, for example, avoiding damage to the droplet generator nozzle head when tin supply is unexpectedly depleted. The disclosed ITSM system 450 monitors the tin stream level and provides advance warning (on the order of five to ten hours) of droplet material depletion, which provides operators plenty of time to take action and prevent the EUVL system 10 from unscheduled downtime, testing and trouble shooting. Such improvements to the system thus improve EUVL tool productivity and wafer per day (WPD) performance.

According to various embodiments, an extreme ultraviolet (EUV) lithography apparatus includes (i) a droplet generator having an inlet port for receiving droplet material from a reservoir via a supply line, (ii) a pressure sensor configured to measure a pressure within the supply line and (iii) a monitoring device configured to detect an increase in the pressure measured by the pressure sensor and to responsively output an indication that the reservoir requires refill of the droplet material. In some embodiments, the reservoir is configured to heat and pressurize the droplet material. In some embodiments, the reservoir includes a primary reservoir and a secondary reservoir. In some embodiments, the primary reservoir and the secondary reservoir are interconnected so that an amount of droplet material in the primary reservoir is equal to an amount of droplet material in the secondary reservoir during normal operation of the EUV apparatus. In some embodiments, the secondary reservoir is connected to a refill tank in order to receive droplet material when the primary reservoir and the secondary reservoir are substantially depleted. In some embodiments, a storage capacity of the secondary reservoir is greater than a storage capacity of the primary reservoir. In some embodiments, the primary reservoir and the secondary reservoir are disposed vertically, and a bottom of the primary reservoir is disposed at substantially the same height as a bottom of the secondary reservoir. In some embodiments, a conduit is connected to the supply line, wherein the pressure sensor is disposed within the conduit in proximity to a junction of the supply line and the conduit. In some embodiments, junction is disposed at a location that is closer to the inlet port than the reservoir. In some embodiments, the conduit is disposed through a sidewall of the supply line. In some embodiments, the monitoring device is further configured to output at least one of an alarm and a shutdown command. In some embodiments, the monitoring device is further configured to output a command to refill the reservoir.

According to various embodiments, an extreme ultraviolet (EUV) lithography apparatus includes a droplet generator having an inlet port for receiving a droplet material from a supply line. The apparatus also includes a primary reservoir configured to provide droplet material to the supply line, a reserve reservoir configured to provide droplet material to the primary reservoir, and a refill tank configured to refill the reserve reservoir before the primary and reserve reservoir are depleted of droplet material. In some embodiments, the primary reservoir and the reserve reservoir are interconnected so that an amount of droplet material in the primary reservoir is substantially equal to an amount of droplet material in the reserve reservoir during normal operation of the droplet generator. In some embodiments, the primary reservoir and the secondary reservoir are disposed vertically, and a bottom of the primary reservoir is disposed at about the same height as a bottom of the secondary reservoir. In some embodiments, the secondary reservoir is also connected to a refill tank that is configured to provide additional droplet material when the primary reservoir and the secondary reservoir are substantially depleted. In some embodiments, a storage capacity of the secondary reservoir is greater than a storage capacity of the primary reservoir to allow refilling of the primary reservoir by the secondary reservoir.

According to various embodiments, an extreme ultraviolet (EUV) lithography apparatus includes a droplet generator having an inlet port for receiving a droplet material from a supply line, a primary reservoir connected to the supply line, a reserve reservoir connected to primary reservoir and the supply line. The reserve reservoir is also connected to a refill tank. The apparatus also includes a pressure sensor configured to measure a pressure within the supply line. In such embodiments, a monitoring device configured to detect a spike in the pressure measured by the pressure sensor and to responsively trigger a refill tank to refill the reserve reservoir. In some embodiments, the primary reservoir and the reserve reservoir are connected such that an amount of droplet material in the primary reservoir and the reserve reservoir are equal. In some embodiments, the monitoring device is further configured to responsively shutdown the droplet generator.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An extreme ultraviolet (EUV) lithography apparatus, comprising:
a droplet generator having an inlet port for receiving droplet material from a reservoir via a supply line;
a pressure sensor configured to measure a pressure within the supply line; and
a monitoring device configured to detect an increase in the pressure measured by the pressure sensor and to responsively output an indication that the reservoir requires refill of the droplet material.

2. The apparatus of claim 1, wherein the reservoir is configured to heat and pressurize the droplet material.

3. The apparatus of claim 1, wherein the reservoir comprises a primary reservoir and a secondary reservoir.

4. The apparatus of claim 3, wherein the primary reservoir and the secondary reservoir are interconnected so that an amount of droplet material in the primary reservoir is equal to an amount of droplet material in the secondary reservoir during normal operation of the EUV apparatus.

5. The apparatus of claim 4, wherein the secondary reservoir is further connected to a refill tank in order to receive further droplet material when the primary reservoir and the secondary reservoir are substantially depleted.

6. The apparatus of claim 5, wherein a storage capacity of the secondary reservoir is greater than a storage capacity of the primary reservoir.

7. The apparatus of claim 4, wherein the primary reservoir and the secondary reservoir are disposed vertically, and a bottom of the primary reservoir is disposed at the same height as a bottom of the secondary reservoir.

8. The apparatus of claim 1, further comprising a conduit connected to the supply line, wherein the pressure sensor is disposed within the conduit in proximity to a junction of the supply line and the conduit.

9. The apparatus of claim 8, wherein the junction is disposed at a location that is closer to the inlet port than the reservoir.

10. The apparatus of claim 1, wherein the conduit is disposed through a sidewall of the supply line.

11. The apparatus of claim 1, wherein the monitoring device is further configured to output at least one of an alarm and a shutdown command.

12. The apparatus of claim 1, wherein the monitoring device is further configured to output a command to refill the reservoir.

13. An extreme ultraviolet (EUV) lithography apparatus, comprising:
a droplet generator having an inlet port for receiving a droplet material from a supply line;
a primary reservoir configured to provide droplet material to the supply line;
a reserve reservoir configured to provide droplet material to the primary reservoir; and
a refill tank configured to refill the reserve reservoir before the primary and reserve reservoir are depleted of droplet material.

14. The apparatus of claim 13, wherein the primary reservoir and the reserve reservoir are interconnected so that an amount of droplet material in the primary reservoir is substantially equal to an amount of droplet material in the reserve reservoir during operation of the droplet generator.

15. The apparatus of claim 14, wherein the primary reservoir and the secondary reservoir are disposed vertically, and a bottom of the primary reservoir is disposed at the same height as a bottom of the secondary reservoir.

16. The apparatus of claim 13, wherein the secondary reservoir is further connected to a refill tank that is configured to provide additional droplet material when the primary reservoir and the secondary reservoir are depleted.

17. The apparatus of claim 16, wherein a storage capacity of the secondary reservoir is greater than a storage capacity of the primary reservoir.

18. An extreme ultraviolet (EUV) lithography apparatus, comprising:
a droplet generator having an inlet port for receiving a droplet material from a supply line;
a primary reservoir connected to the supply line;
a reserve reservoir connected to primary reservoir and the supply line, the reserve reservoir further connected to a refill tank;
a pressure sensor configured to measure a pressure within the supply line; and
a monitoring device configured to detect a spike in the pressure measured by the pressure sensor and to responsively trigger the refill tank to refill the reserve reservoir.

19. The apparatus of claim 18, wherein the primary reservoir and the reserve reservoir are connected such that an amount of droplet material in the primary reservoir and the reserve reservoir are equal.

20. The apparatus of claim 18, wherein the monitoring device is further configured to responsively shutdown the droplet generator.
